(19) United States
(12) Patent Application Publication
(10) Pub. No.: US 2022/0389278 A1
(43) Pub. Date: Dec. 8, 2022

(54) METHOD FOR PREPARING CERIUM OXIDE PARTICLES, AND POLISHING PARTICLES AND POLISHING SLURRY COMPOSITION COMPRISING SAME

(71) Applicant: CHEMTON CO., LTD., Gyeonggi-do (KR)

(72) Inventors: Seogkyu GO, Ansan-si (KR); Jongsung KIM, Ansan-si (KR); Seohyun WON, Ansan-si (KR)

(73) Assignee: CHEMTON CO., LTD., Gyeonggi-do (KR)

(21) Appl. No.: 17/775,587

(22) PCT Filed: Nov. 5, 2020
(86) PCT No.: PCT/KR2020/015391

§ 371 Date: May 10, 2022

(30) Foreign Application Priority Data
Nov. 11, 2019 (KR) 10-2019-0143231

(51) Int. Cl. C09G 1/02; C01F 17/235

(52) U.S. Cl. CPC C09G 1/02; C01F 17/235; C01P 2002/85

(57) ABSTRACT

The polishing particles of the present disclosure has controlled particle size and particle size distribution of cerium oxide particles comprised in the polishing particles, and thereby can suppress the formation of a scratch which may occur in a polishing process while having a characteristic of a high polishing rate.

### CROSS-REFERENCE TO RELATED APPLICATIONS

This application claims a priority benefit of Korean Patent Application No. 10-2019-0143231 filed on Nov. 11, 2019, in the Korean Intellectual Property Office, the entire disclosure of which is incorporated herein by reference for all purposes.

### TECHNICAL FIELD

The present disclosure relates to polishing particles including cerium oxide particles. In detail, it relates to polishing particles including cerium oxide particles and having improved uniformity in the particle size, included in slurry for CMP (Chemical Mechanical Polishing) for suppressing the occurrence of a scratch on a wafer and presenting a high polishing rate during polishing, and manufacturing methods of a slurry composition for polishing and cerium oxide particles.

### BACKGROUND ART

Cerium oxide particles that are also called as ceria are a functional ceramic material used in many fields such as catalyst and polishing agent, and particularly are being used as a main ingredient of a slurry composition for polishing used in CMP (Chemical Mechanical Polishing) process which is one of manufacturing processes of a semiconductor.

In general, the cerium oxide particles may be synthesized by a gas phase method, a liquid phase method, or a solid phase method. The gas phase method is a method of synthesizing cerium oxide particles by vaporizing a cerium precursor and subsequently reacting the vaporized cerium precursor with oxygen or the like. A manufacturing device for the gas phase method may have a high price, and the mass production may be different. The liquid phase method may have a difficult in an adjustment of a particle size and a dispersion degree between particles. The solid phase method is a method of treating a cerium precursor with heat at a high temperature to crystallize it, and subsequently crushing it to be minute particles, thereby manufacturing cerium oxide particles. The solid phase method may have a possibility of being mixed with impurities and a reaction speed may be relatively low.

### RELATED PRIOR ART

Korean Patent Registration No. 0460102, registered on Nov. 25, 2004, “Manufacturing Method of Ultrafine Particles of Metal Oxide”

Korean Patent Registration No. 1492234, registered on Feb. 4, 2015, “Manufacturing Method of Cerium Oxide Particles, Cerium Oxide Particles Manufactured from the Method and Polishing Slurry Comprising the Same”

### DETAILED DISCLOSURE

### Technical Problem

An objective of the present disclosure is providing polishing particles including cerium oxide particles, in which a particle size distribution of the cerium oxide particles is adjusted, to suppress a frequency of an occurrence of scratches, which can be caused from a polishing process when being applied to a slurry composition for polishing, with presenting a high polishing rate.

### Technical Solution

To solve the above objective, polishing particles according to one embodiment disclosed in the present specification include cerium oxide particles in which a particle size distribution of secondary particles according to Equation 1 below (1) is 1.42 or less.

The particle size distribution=(D₉₀−D₁₀)/D₅₀ Equation (1)

In the Equation (1), the D₁₀ refers to a particle size of a spot of 10% from a cumulative particle size distribution curve, the D₅₀ refers to a particle size of a spot of 50% from the cumulative particle size distribution curve, and the D₉₀ refers to a particle size of a spot of 90% from the cumulative particle size distribution curve.

In the polishing particles, wherein the cerium oxide particles may have a ratio of O—Ce peak area:O—C peak area measured by XPS (X-ray Photoelectron Spectroscopy), which is 1:1.15 to 1.40.

In the polishing particles, the cerium oxide particles may have an average particle size of primary particles, which is 28 nm or less.

In the polishing particles, the cerium oxide particles may have an average particle size of secondary particles, which is 140 nm or less.

The polishing particles may include cerium oxide particles doped by at least one metal atom among Zn, Co, Ni, Fe, Al, Ti, Ba and Mn.

A slurry composition for polishing according to another embodiment disclosed in the present specification includes the polishing particles and a dispersant.

The slurry composition for polishing according to another embodiment disclosed in the present specification may include the polishing particles and dispersant.

The slurry composition for polishing may further include any one selected from the group consisting of a pH regulator, a viscosity regulator, and combinations thereof.

The slurry composition for polishing may have a polishing rate of 2750 to 5500 Å/min for a silicon oxide film.

The slurry composition for polishing may have a decreased defect occurrence rate which is 60% or less, compared to cerium oxide particles applied with ammonia as a precipitant, when a silicon oxide film is polished.

An use of cerium oxide particles according to another embodiment disclosed in the present specification is polishing particles applied to a polishing process of a semiconductor wafer.

The cerium oxide particles may have a particle size distribution of secondary particles which is 1.42 or less according to Equation (1) below.

The distribution of the particle size=(D₉₀−D₁₀)/D₅₀ Equation (1)

In the Equation (1), the D₁₀ refers to a particle size of a spot of 10% from a cumulative particle size distribution curve, the D₅₀ refers to a particle size of a spot of 50% from the cumulative particle size distribution curve, and the D₉₀ refers to a particle size of a spot of 90% from the cumulative particle size distribution curve.

The cerium oxide particles may have a ratio of O—Ce peak area:O—C peak area measured by XPS (X-ray Photoelectron Spectroscopy), which is 1:1.15 to 1.40.

The cerium oxide particles may have an average particle size of primary particles, which is 28 nm or less.

The cerium oxide particles may have an average particle size of secondary particles, which is 140 nm or less.

The cerium oxide particles may be doped by at least one metal atom among Zn, Co, Ni, Fe, Al, Ti, Ba and Mn.

A polishing method according to one embodiment disclosed in the present specification may apply a slurry composition for polishing including the cerium oxide particles and thereby polishes a surface of a substrate.

The substrate may be for example, a semiconductor wafer.

The description of the cerium oxide particles, the slurry composition for polishing, and the like are overlapped with the description in other portions of the present specification and thus the further description is omitted.

A manufacturing method of cerium oxide particles according to another embodiment disclosed in the present specification includes a preparation operation of preparing a composition for reaction including a cerium precursor and an ammonia precursor; and

a synthesis operation of obtaining cerium oxide particles reacted in a supercritical fluid or a subcritical fluid.

The ammonia precursor is a compound which forms a pyrolyzate including ammonia at an atmosphere of 80° C.

The cerium oxide particles have a particle size distribution of secondary particles according to Equation (1) below, which is 1.42 or less.

The particle size distribution=(D₉₀−D₁₀)/D₅₀ Equation (1)

In the Equation (1), the D₁₀ refers to a particle size of a spot of 10% from a cumulative particle size distribution curve, the D₅₀ refers to a particle size of a spot of 50% from the cumulative particle size distribution curve, and the D₉₀ refers to a particle size of a spot of 90% from the cumulative particle size distribution curve.

In the manufacturing method, the ammonia precursor may include urea.

In the manufacturing method, the cerium precursor may include nitrogen in a molecule thereof.

In the synthesis operation, the reaction may proceed in an atmosphere of 250° C. or more.

In the manufacturing method, the composition for reaction may further include a metal precursor for doping.

In the manufacturing method, the composition for reaction may have a solution form in which the cerium precursor and the ammonia precursor have been dispersed.

In the manufacturing method, the composition for reaction may include the ammonia precursor to have a mole ratio of the nitrogen atoms to the ammonia, which is 0.7 to 1.5.

In the manufacturing method, the composition for reaction may include the metal precursor for doping in an amount of 0.5 to 1 part by weight based on the cerium precursor of 100 parts by weight.

In the manufacturing method, the composition for reaction may include the ammonia precursor in an amount of 15 to 60 parts by weight based on the cerium precursor of 100 parts by weight.

### Advantageous Effects

The polishing particles including the cerium oxide particles of the present disclosure have a relatively small particle size and comparatively uniform distribution of the particle size, while presenting a high polishing rate with suppressing the occurrence of scratches when being used in CMP (Chemical Mechanical Polishing) process.

### DETAILED DESCRIPTION OF EXEMPLARY EMBODIMENTS

Hereinafter, example embodiments of the present disclosure will be described in detail with reference to the accompanying drawings so that they can be easily practiced by those skilled in the art to which the present invention pertains. However, the example embodiments may be embodied in many different forms and is not to be construed as being limited to the embodiments set forth herein.

In this specification, the term of “˜” based refers to including a compound corresponding to “˜” or derivatives of “˜” in a compound.

Throughout this specification, a singular form is contextually interpreted as including a plural form as well as a singular form unless specially stated otherwise.

Inventors of the present disclosure discovered that when a cerium oxide particles were manufactured by a conventional solid phase method, sizes of the manufactured particles became relatively large. Also, it was discovered when ammonia was used as a precipitant in the process of synthesizing cerium oxide particles by using a supercritical fluid or a subcritical fluid, the particles sizes are reduced but a particle size distribution became broad. When cerium oxide particles of which particles sizes are relatively large or particle size distribution is not regulated, are used in CMP (Chemical Mechanical Polishing) process, many scratches may occur on a wafer as a polishing target. Accordingly, inventors of the present disclosure searched a manufacturing method of cerium oxide particles of which the sizes are small and whose particle size distribution is comparatively uniformed. And the inventors ascertained the effects of reducing the sizes of the manufactured cerium oxide particles and uniformizing the particle size distribution relatively, when an ammonia precursor was applied in synthesis of cerium oxide particles in a supercritical fluid or a subcritical fluid, thereby completing the present disclosure.

Hereinafter, the present disclosure will be described in further detail.

Polishing particles according to one embodiment of the present specification comprise cerium oxide particles in which a particle size distribution of secondary particles according to Equation (1) below, which is 1.42 or less.

The particle size distribution=(D₉₀−D₁₀)/D₅₀ Equation (1)

In the Equation (1),

the D₁₀ refers to a particle size of a spot of 10% from a cumulative particle size distribution curve,

the D₅₀ refers to a particle size of a spot of 50% from the cumulative particle size distribution curve, and

the D₉₀ refers to a particle size of a spot of 90% from the cumulative particle size distribution curve.

The polishing particles comprise plural cerium oxide particles having a slight difference in the size, shape, and the like from respective particles. The present specification uses a term of polishing particles, for indicating plural polishing particles or a polishing particle composition comprising plural polishing particles.

Primary particles refer to grains of cerium oxide generated immediately after a synthesis reaction of cerium oxide. Secondary particles refer to particles having sizes in a certain range that are formed by naturally cohering of the primary particles from one another during the flow of time.

D₁₀, D₅₀ and D₉₀ values may for example, measured by using Zetasizer Nano ZS apparatus available from MALVERN.

The polishing particles may comprise cerium oxide particles having a particle size distribution of secondary particles according to Equation (1), which is 1.42 or less. The polishing particles may comprise cerium oxide particles having the particle size distribution of secondary particles according to Equation (1), which is 1.41 or less. In such a case, frequency of scratches occurring on a wafer can be reduced when polishing is performed by slurry for CMP comprising cerium oxide particles.

The cerium oxide particles may comprise a carbon atom on a surface thereof. The cerium oxide particles may have a high amount of carbon in the particle thereof, compared to cerium oxide particles manufactured by applying ammonia as a precipitant. This is thought to have a reason in a carbon atom comprised in an ammonia precursor used in the manufacture of the cerium oxide particles. The inventors ascertained through experiments that the cerium oxide particles may have a comparatively uniformized particle size distribution when the carbon amount of the surface thereof is high.

A comparison of a carbon content between the above cerium oxide particles and the cerium oxide particles manufactured by applying ammonia as a precipitant can be judged by measuring the O—Ce peak area:O—C peak area by XPS (X-ray Photoelectron Spectroscopy). The area of O—Ce peak area:O—C peak area in XPS can be measured by using K-ALPHA apparatus available from THERMO FISHER SCIENTIFIC.

A ratio of the O—Ce peak area:O—C peak area measured by XPS for the cerium oxide particles comprised in the polishing particles may be 1:1.15 to 1.40. The ratio may be 1:1.20 to 1.35. In such a case, the cerium oxide particles may have a comparatively uniformed particle size distribution.

The cerium oxide particles may have an average particle size of primary particles, which is 28 nm or less. The average particle size may be 25 nm or less. In such a case, frequency of scratches occurring in a wafer may be decreased in CMP process.

A measurement of the average particle size of the primary particles of cerium oxide is made by analyzing XRD (X-Ray Diffraction) of samples of cerium oxide particles, measuring FWHM (Full Width Half Maximum) of a main peak, and calculating the average particle size through putting FWMH into Scherrer formula (Equation (2) below).

$$t = \frac{k \times λ}{B cos {θ}_{B}} \qquad Equation ( 2 )$$

In the Equation (2),

the t refers to the average size of particles,

the k refers to a constant value (substituting 0.94 for the k),

the λ refers to a wavelength of X-Ray,

the B refer to FWHM, and

the θ_{B} refers to a value of a half of Bragg angle (2θ_{B}).

For example, XRD may be measured by using SmartLab SE apparatus available from RIGAKU.

The cerium oxide particles may have an average particle size of secondary particles, which is 140 nm or less. The average particle size may be 138 nm or less. In such a case, frequency of scratches occurring in a wafer in CMP process may be decreased. For example, the average particle size of secondary particles of cerium oxide may be measured through Zetasizer Nano ZS apparatus available from MALVERN. A method of calculating the average particle size of secondary particles is applied by Equation (3) below for calculating Z average value of the particle size.

$${D}_{Z} = \frac{\sum {S}_{i}}{\sum ( {S}_{i} / {D}_{i} )} \qquad Equation ( 3 )$$

In the Equation (3),

the D_{z} refers to the average size of the cerium oxide secondary particles,

the Sᵢ refers to a scattering intensity of particles, and

the Dᵢ refers to the size of particles.

The polishing particles may comprise cerium oxide particles doped by at least any one metal atom among Zn, Co, Ni, Fe, Al, Ti, Ba and Mn, but are not limited thereto.

When cerium oxide particles are doped by the metal atom, a slurry composition comprising the cerium oxide particles can have the characteristic of a high polishing rate. When cerium oxide particles are doped by the metal atom, oxygen vacancy occurs on the surfaces of cerium oxide particles, and a concentration of Ce³⁺ becomes high in the surfaces of cerium oxide particles. Ce³⁺ has a characteristic of reducing other compounds, and the cerium oxide particles having a high Ce³⁺ concentration in the surface thereof can make chemical polishing on a wafer surface be more efficient by reaction with SiO₂ thin film present on the wafer surface, through utilizing such a characteristic.

A slurry composition for polishing according to another embodiment comprises the polishing particles. The description of the polishing particles is overlapped with the above description and thus omitted.

The slurry composition for polishing may comprise a polishing additive for dispersion stabilization and chemical stabilization between the polishing particles. The polishing additive may further comprise at least any one selected from the group consisting of a dispersant, a pH regulator, a viscosity regulator, and combinations thereof.

The dispersant functions as stabilizing the dispersion of the slurry composition for polishing by dispersing cohered polishing particles. An anion-based polymer compound comprising a carboxyl group may be used as the dispersant. The anion-based polymer compound comprising a carboxyl group may have suitable solubility for water at room temperature. In slurry, which is water media, the anion-based polymer compound comprising a carboxyl group can stabilize the dispersion of a slurry composition with suitable solubility.

The anion-based polymer comprising a carboxyl group may be for example, at least one selected from the group consisting of polyacrylic acid, poly styrene sulfonic acid, polymethyl methacrylate, ammonium polycarboxylate, carboxylic acrylpolymer, and combinations thereof, but is not limited thereto.

The slurry composition for polishing may comprise a dispersant of 0.5 to 10 parts by weight parts by supposing the cerium oxide particles as 100 parts by weight. The slurry composition for polishing may comprise a dispersant of 1 to 5 parts by weight by supposing the cerium oxide particles as 100 parts by weight. In such a case, the polishing particles comprised in the slurry composition for polishing can be sufficiently dispersed, and the occurrence of wafer scratches can be suppressed in a polishing process.

The pH regulator can regulate pH of the slurry composition for polishing to present a high polishing rate when a wafer is polished. When the polishing particles comprise cerium oxide particles, the pH of the slurry composition for polishing which can show a high polishing rate may be 4 to 10. The pH regulator may comprise, for example, one selected from the group consisting of potassium hydroxide, ammonia, sodium hydroxide, magnesium hydroxide, sodium hydrogen carbonate, sodium carbonate, nitric acid, sulfuric acid, phosphoric acid, hydrochloric acid, acetic acid, formic acid and combinations thereof, but is not limited thereto.

The viscosity regulator may regulate the viscosity of a slurry composition for polishing and thereby can improve the polishing uniformity of a wafer. A viscosity of the slurry composition for polishing may be 0.5 to 3.2 cps (centi poise). The viscosity may be 1.2 to 2.4 cps. The viscosity regulator may be a fatty acid ester comprising polyhydric alcohol, a fatty acid ester comprising polyoxyethylene sorbitan, and the like, but is not limited thereto.

The slurry composition for polishing may have a polishing rate of 2750 to 5500 Å/min for a silicon oxide film of a wafer when applied to CMP process. The polishing rate may be 3000 to 5000 Å/min. The measuring condition and measuring data for the polishing rate are described in detail in Examples below.

The slurry composition for polishing may have a defect (occurring on a wafer) occurrence rate which is decreased to be 60% or less, compared to a slurry composition for polishing comprising cerium oxide particles applied with ammonia as a precipitant. The defect occurrence rate may be decreased to be 50% or less. The measuring condition and measuring data for the defect occurrence rate are described in detail in Examples below.

An use of cerium oxide particles according to another embodiment disclosed in the present specification is polishing particles applied to a polishing process of a semiconductor wafer. The use of cerium oxide particles may be an abrasive comprised in slurry for polishing. A description of the cerium oxide particles is overlapped with the above description in detail and thus omitted.

A polishing method according to another embodiment disclosed in the present specification may apply a slurry composition for polishing comprising the cerium oxide particles and thereby polishes a surface of a substrate. The substrate may be for example, a semiconductor wafer. A description of the cerium oxide particles and the slurry composition for polishing is overlapped with the above description in detail and thus omitted.

A manufacturing method of cerium oxide particles according to another embodiment of the present specification comprises a preparation operation of preparing a composition for reaction comprising a cerium precursor and an ammonia precursor; and a synthesis operation of obtaining cerium oxide particles reacted in a supercritical fluid or a subcritical fluid.

In the preparation operation, the cerium precursor may be for example, one selected from a group consisting of a cerium nitrate, ammonium nitrate, sulfate, chloride, carbonate, acetate, phosphate, and combinations thereof, but is not limited thereto.

In the preparation operation, the composition for reaction may be a composition in a form of dispersed cerium precursor and ammonia precursor. The ammonia precursor may have a characteristic of relatively low reactivity compared to another compound which can be applied as a coagulant (for example: ammonia). Due to the above, the ammonia precursor in the composition for reaction may be evenly distributed in the preparation operation before the cohesion reaction between the ammonia precursor and the cerium precursor rapidly proceeds with a high speed. Subsequently, in the synthesis operation, the ammonia precursor is pyrolyzed to be ammonia in the supercritical fluid or the subcritical fluid, and the ammonia is allowed to perform cohesion reaction with a cerium precursor, to regulate the particle size distribution of cerium oxide particles to be relatively uniformed.

The ammonia precursor may be a nitrogen compound which is pyrolyzed in an atmosphere of 80° C. or more to form ammonia or a compound comprising an ammonium group. The ammonia precursor may be for example, any one selected from the group consisting of urea, ammonium carbonate, ammonium carbamate, and combinations thereof.

The cerium precursor may comprise a nitrogen atom in the molecule thereof. When a nitrogen atom is comprised in the cerium precursor, a nitrogen compound (for example: NO₃⁻) may be formed in the synthesis operation as a by-product. When the synthesis operation proceeds in a supercritical fluid or a subcritical fluid, the nitrogen oxide is decomposed through reaction between the nitrogen compound as a by-product and ammonia and thereby an emission amount of the by-product can be reduced.

An amount of the ammonia precursor comprised in a composition for reaction may be different depending on an amount of nitrogen atoms comprised in a molecule of the cerium precursor. The composition for reaction may comprise the ammonia precursor to have a mole ratio of 1:0.7 to 1.5 between the nitrogen atoms and the ammonia comprised in the molecule of a cerium precursor. The composition for reaction may comprise the ammonia precursor to have a mole ratio of 1:0.9 to 1.2 between the nitrogen atoms and the ammonia comprised in the molecule of a cerium precursor. The composition for reaction may comprise the ammonia precursor of in an amount of 15 to 60 parts by weight based on the cerium precursor of 100 parts by weight. The composition for reaction may comprise the ammonia precursor in an amount of 30 to 55 parts by weight based on the cerium precursor of 100 parts by weight. In such a case, the productivity of the cerium oxide particles can be improved, and the decomposition of the nitrogen oxide as a by-product can be furthered, and content of the ammonia remaining in an emitted solution cannot be excessively heightened.

In the synthesis operation, by using characteristic of the low density and the low dielectric constant of a supercritical fluid or subcritical fluid, the speed of nucleus formation reaction of cerium oxide particles.

The synthesis operation comprises a process of forming cerium hydroxide from the cerium precursor hydrated in the supercritical fluid the a subcritical fluid, a process of forming a nucleus from cerium hydroxide supersaturated in a supercritical fluid or a subcritical fluid, a process of growing cerium oxide particles from the nucleus, and a process of obtaining cerium oxide particles through a subsequent dehydrating process.

The supercritical fluid or the subcritical fluid may be for example, supercritical water, supercritical alcohol, supercritical carbon dioxide, supercritical alkane, and the like, but is not limited thereto.

A temperature of the supercritical fluid or subcritical fluid may be 250° C. to 600° C. The temperature of the supercritical fluid or subcritical fluid may be 300° C. to 500° C. The pressure of the supercritical fluid or subcritical fluid may be 50 bar to 500 bar. A pressure of the supercritical fluid of subcritical fluid may be 100 bar to 400 bar. In such a case, a uniformity of the particle size distribution of synthesized cerium oxide particles can be improved, amount of a by-product can be decreased, a production cost can be optimized, and the re-dissolution of the cerium oxide particles can be suppressed.

In the synthesis operation, the composition for reaction may be added in an atmosphere of 250° C. or more. In the synthesis operation, the composition for reaction may be added in an atmosphere of 300° C. or more. In such a case, the cerium oxide particles showing a relatively uniformized particle sizes can be obtained, and the nitrogen compound which is a by-product can be sufficiently decomposed.

In the synthesis operation, time of synthesis reaction of cerium oxide particles may be 30 seconds to 10 minutes. The time of synthesis reaction of cerium oxide particles may be 40 seconds to 5 minutes. In such a case, the cerium oxide particles may show a relatively uniformized particle size distribution.

The cerium oxide particles obtained through the preparation operation and the synthesis operation may have the particle size distribution of secondary particles which is 1.42 or less according to Equation (1) below.

The distribution of the particle size=(D₉₀−D₁₀)/D₅₀ Equation (1)

In the Equation (1), the D₁₀ refers to a particle size of a spot of 10% from a cumulative particle size distribution curve, the D₅₀ refers to a particle size of a spot of 50% from the cumulative particle size distribution curve, and the D₉₀ refers to a particle size of a spot of 90% from the cumulative particle size distribution curve.

A description of primary particles and secondary particles and a description of a measuring device for D₁₀, D₅₀ and D₉₀ are overlapped with the above description in detail and thus omitted.

The cerium oxide particles obtained through the preparation operation and the synthesis operation may have the particle size distribution of secondary particles which is 1.42 or less according to Equation (1). In such a case, when a slurry for polishing comprising the cerium oxide particles is applied to CMP process, a damage of a polished material can be suppressed.

In the preparation operation of the manufacturing method of cerium oxide particles, a metal precursor for doping may be further comprised, and the doped cerium oxide particles can be manufactured. A surface of the cerium oxide particles is doped, and the reducing power of cerium oxide particles is improved and thereby a polishing rate of slurry comprising the cerium oxide particles can be improved.

In the preparation operation, the metal precursor for doping may be comprised in an amount of 0.6 to 1 parts by weight based on the cerium precursor of 100 parts by weight. The metal precursor for doping may be comprised in an amount of 0.7 to 0.8 parts by weight. In such a case, a polishing rate of slurry comprising the cerium oxide particles can be improved.

Hereinafter, the present disclosure will be described in further detail through example embodiments. The example embodiments are no more than examples for helping to understand the present disclosure, and the range of the present invention is not limited thereto.

### MANUFACTURE EXAMPLE

### Synthesis of Particles

### Comparative Example 1

Cerium oxide particles were manufactured by a solid phase method. In detail, cerium carbonate as an insoluble precursor was dried for removal of the moisture thereof, and calcinated at 700° C. for removal of combined water and carbon dioxide, thereby obtaining cerium oxide particles.

### Comparative Example 2

Nitrogen cerium was dissolved in deionized water and thereby, a composition for reaction as a nitrogen cerium solution of 20 wt % was prepared. Ammonia water was prepared to have a content of 25 wt %.

The composition for reaction and the ammonia water of the flow rate of respectively 20 ml/min were introduced in a supercritical reactor and mixed with supercritical water of 100 ml/min at 400° C. with 250 bar, to perform supercritical hydrothermal synthesis reaction. Thereafter, a cerium oxide particles were obtained by methods such as cooling and centrifugation.

### Comparative Example 3

While cerium oxide particles were manufactured in a same manner as a method of Comparative Example 2, an aqueous solution containing cerium nitrate of 20 wt % and aluminum nitrate of 0.073 wt %, manufactured by dissolving cerium nitrate and aluminum nitrate as a metal precursor for doping in deionized water, was applied as a composition for reaction.

### Example 1

Cerium nitrate and urea were dissolved in deionized water and thereby a composition for reaction, which was an aqueous solution containing cerium nitrate of 20 wt % and urea of 4.8 wt %, was prepared.

The composition for reaction was introduced in a supercritical reactor in a flow rate of 40 ml/min and mixed with supercritical water of 100 ml/min at 400° C. with 250 bar, to perform supercritical hydrothermal synthesis reaction. Thereafter, cerium oxide particles were obtained by methods such as cooling and centrifugation.

### Example 2

While cerium oxide particles were manufactured in a same manner as the method of Example 1, an aqueous solution containing cerium nitrate of 20 wt % and aluminum nitrate of 0.073 wt %, manufactured by dissolving cerium nitrate and aluminum nitrate as a metal precursor for doping in deionized water, was applied as a composition for reaction.

### EVALUATION EXAMPLE

### Property Evaluation of Particles

[Observation of Transmitting Electronic Microscope]

Electronic microscope photos of cerium oxide particles synthesized in Example 1, Example 2, Comparative Example 2, and Comparative Example 3 were measured by using CM200 apparatus available from PHILIPS.

As a result of the measurement, it could be ascertained that a size of large one among primary particles of Comparative Example 2 was much larger than one of Example 1 and a particle size distribution of the primary particles was ununiform overall.

In addition, it could be ascertained that a size of large one among primary particles of Comparative Example 3 was much larger than one of Example 2 and a particle size distribution of was not even overall.

[An Average Particle Size by Using XRD]

Respective XRD of particle samples of Examples 1 and 2, and Comparative Examples 1 to 3 were measured by using SmartLab SE apparatus available from RIGAKU, and an average size of primary particles was calculated from FWHM (full width half maximum) of a main peak and results were shown in Table 1 below. A method of calculating the average size of primary particles was applied by Scherrer formula (Equation (2) below).

$$t = \frac{k \times λ}{B cos {θ}_{B}} \qquad Equation ( 2 )$$

In the Equation (2), the t refers to an average size of particles, the k refers constant value (substituting 0.94 for the k), the λ refers to a wavelength of X-Ray, the B refer to FWHM, and the θ_{B} refers to a value of a half of Bragg angle (2θ_{B}).

As a result of the measurement, it could be ascertained that while Example 1, Example 2, Comparative Example 2, and Comparative Example 3 that used supercritical water to synthesize cerium oxide particles had the size of primary particles of no more than 20 to 22 nm, Comparative Example 1 that used a conventional solid phase method to synthesize cerium oxide particles had the size of primary particles of 30 nm, and thereby size values of primary particles had a great difference depending on the manufacturing method.

[Measurement of Particle Size Distribution]

A particle size distribution of respective samples of Examples 1 and 2, and Comparative Examples 2 and 3 was measured by using Zetasizer Nano ZS apparatus available from MALVERN, and D₁₀, D₅₀ and D₉₀ values were shown in Table 2 below, respectively. The apparatus measured a Zeta Potential of colloid particles by a light scattering method, thereby deriving the particle size and the particle size distribution.

As a result of the measurement, comparing Example 1 and Comparative Example 2 of which metal precursors for doping were different each other, even though the examples did not present a great difference an regarding to average size of secondary particles, Example 1 applied with urea was observed to have a lower particle size distribution, compared to Comparative Example 2 applied with ammonia.

Comparing Example 2 and Comparative Example 3 of which metal precursors for doping were the same, the examples did not present a great difference regarding to average size of secondary particles as the same as the above, but Example 2 applied with urea was observed to have a lower particle size distribution, compared to Comparative Example 3 applied to ammonia.

[XPS Analysis]

Particle samples of Examples 1 and 2, and Comparative Examples 2 and 3 were analyzed by XPS (X-ray photoelectron spectroscopy) with K-ALPHA model available from THERMO FISHER SCIENTIFIC. A monochromatic aluminum X-ray source of 12 kW and 10 mA was applied as an X-ray source, and a diameter of 400 μm was sampled. O—C peak area and O—Ce peak area were calculated from the measured result, respectively, and a ratio thereof was obtained, with being shown in Table 2 below.

As a result of the measurement, comparing Example 1 and Comparative Example 2 of which metal precursors for doping were different each other, Example 1 applied with urea presented a higher ratio of the peak area, compared to Comparative Example 2 applied with ammonia. This means that a carbon amount of cerium oxide particles of Example 1 is higher than that of particles of Comparative Example 2.

Comparing Example 2 and Comparative Example 3 of which metal precursors for doping were the same, Example 2 applied 2 showed a higher ratio of the peak area, compared to Comparative Example 3 applied with ammonia. This means a carbon amount of cerium oxide particles of Example 2 is higher than that of a particles of Comparative Example 3.

[Measurement of Polishing Rate]

A thickness of a wafer in which an oxide film in a thickness of 13,000 Å was formed on silicon (Si) through CVD deposition method was applied to the thickness of the initial wafer, by measurement with a thickness measuring device using optical reflectance measurement principle.

A slurry composition containing cerium oxide particles manufactured in the above was manufactured, a polishing condition indicated in Table 3 below was applied, and thereby CMP (Chemical Mechanical Polishing) process was performed under all the same conditions. A polishing rate, a defect number, and a defect occurrence rate of an oxide film after the CMP process were measured, and a result was shown in Table 3 below.

The slurry composition was manufactured by mixing cerium oxide polishing particles of 5 wt %, with an anion polymer as a dispersant and polyacrylic acid (PAA) of respectively 1.7 wt % compared to the amount of cerium oxide polishing particles, and adding a pH regulator to have pH of 8.5.

TABLE 1

| | | | | | | | The Flow rate | | | |
|---|---|---|---|---|---|---|---|---|---|---|
| | | | Reactant 1 | | | Reactant 2 | of Fluid (ml/min) | | | |
| | | | (Content, wt %) | | | (Content, wt %) | Super | | | Particle |
| | Temperature | Pressure | Cerium | | Aluminum | Ammonia | critical | Reactant | Reactant | Size |
| | (° C.) | (bar) | Nitrate | Urea | Nitrate | Water | Water | 1 | 2 | XRD(nm) |
| Comparative | Solid Phase | | — | | | | | | | 30 |
| Example 1 | Method for | | | | | | | | | |
| | Mass | | | | | | | | | |
| | Production | | | | | | | | | |
| Example 1 | 400 | 250 | 10 | 4.8 | — | — | 100 | 40 | 0 | 22 |
| Comparative | 400 | 250 | 20 | — | — | 25 | 100 | 20 | 20 | 21 |
| Example 2 | | | | | | | | | | |
| Example 2 | 400 | 250 | 10 | 4.8 | 0.073 | — | 100 | 40 | 0 | 20 |
| Comparative | 400 | 250 | 20 | — | 0.073 | 25 | 100 | 20 | 20 | 22 |
| Example 3 | | | | | | | | | | |

TABLE 2

| | | | | Particle | | O—C | O—Ce | The Ratio of |
|---|---|---|---|---|---|---|---|---|
| | | | | Size | | Peak | Peak | Peak Area |
| | D10(nm) | D50(nm) | D90(nm) | Distribution | Z-Size | Area* | Area* | (O—Ce:O—C) |
| Example 1 | 79.6 | 152 | 278 | 1.305 | 136.4 | 83.38 | 68.35 | 1:1.22 |
| Comparative | 71.9 | 158 | 325 | 1.602 | 135.7 | 65.32 | 61.05 | 1:1.07 |
| Example 2 | | | | | | | | |
| Example 2 | 78.2 | 156 | 299 | 1.415 | 135 | 88.65 | 67.45 | 1:1.31 |
| Comparative | 72.5 | 152 | 311 | 1.569 | 132.5 | 82.12 | 74.04 | 1:1.11 |
| Example 3 | | | | | | | | |

*XPS Measuring Condition
X-ray source: Monochromated Al X-Ray sources
X-Ray power: 12 kV, 10 mA.
Sampling area: 400 um (diameter).
Narrow scan: pass energy 50 eV, step size 0.1 eV.
Calibration: Not Applied

TABLE 3

| | Polishing Rate of | | The Defect |
|---|---|---|---|
| | Silicon Oxide Film | Defect | Occurrence |
| | (Åmin) | (ea) | Rate* |
| Comparative | 3852 | 531 | — |
| Example 1 | | | |
| Example 1 | 3005 | 367 | 55% |
| Comparative | 2696 | 668 | |
| Example 2 | | | |
| Example 2 | 4738 | 379 | 56% |
| Comparative | 4353 | 673 | |
| Example 3 | | | |

*Polishing Condition
-. Mixing Ratio of Slurry (Slurry:Deionized Water (DI Water) = 1:10)
-. Wafer: 300 mm TEOS Blanket Wafer
-. Pressure: Head 3.0 psi/R-Ring 3.6 Psi
-. Carrier/Platen Speed (RPM): 100/101
-. Flux: 250 ml
*Defect Occurrence Rate (%)
=(The Defect Number when Particles Applied with Urea Was Applied/The Defect Number when Particles Applied with Ammonia Was Applied)*100

As a result of the measurement, comparing Example 1 and Comparative Example 2 of which metal precursors for doping were different each other, the defect occurrence number of Example 1 applied with urea was no more than 55% of the defect occurrence number of Comparative Example 2 applied with ammonia.

Comparing Example 2 and Comparative Example 3 of which metal precursors for doping were the same, the defect occurrence number of Example 2 applied with urea was no more than the defect occurrence number of 56% of Comparative Example 3 applied with ammonia.

Although the exemplary embodiments have been described in detail, a scope of the present invention is not limited thereto, and modifications and alterations made by those skilled in the art using a basic concept of the present invention defined in a following claims fall within the scope of the present invention.

What is claimed is:

1. A polishing particles comprising cerium oxide particles in which a particle size distribution of secondary particles according to Equation 1 below (1) is 1.42 or less;
The particle size distribution=(D₉₀−D₁₀)/D₅₀ Equation (1)
where in the Equation (1),
the D₁₀ refers to a particle size of a spot of 10% from a cumulative particle size distribution curve,
the D₅₀ refers to a particle size of a spot of 50% from the cumulative particle size distribution curve, and
the D₉₀ refers to a particle size of a spot of 90% from the cumulative particle size distribution curve.

2. The polishing particles of claim 1,
wherein the cerium oxide particles have a ratio of O—Ce peak area:O—C peak area measured by XPS (X-ray Photoelectron Spectroscopy), which is 1:1.15 to 1.40.

3. The polishing particles of claim 1,
wherein the cerium oxide particles have an average particle size of primary particles, which is 28 nm or less, and
the cerium oxide particles have an average particle size of secondary particles, which is 140 nm or less.

4. The polishing particles of claim 1, comprising:
cerium oxide particles doped by at least one metal atom among Zn, Co, Ni, Fe, Al, Ti, Ba and Mn.

5. A slurry composition for polishing comprising:
the polishing particles according to claim 1 and a dispersant.

6. The slurry composition for polishing of claim 5,
wherein the dispersant comprises a carboxyl group in a molecule thereof.

7. The slurry composition for polishing of claim 5,
wherein the slurry composition has a polishing rate of 2750 to 5500 Å/min for a silicon oxide film, and
wherein the slurry composition for polishing has a defect occurrence rate which is decreased to be 60% or less, compared to cerium oxide particles applied with ammonia as a precipitant, when a silicon oxide film is polished.

8. A manufacturing method of cerium oxide particles comprising:
a preparation step of preparing a composition for reaction that comprises a cerium precursor and an ammonia precursor; and
a synthesis step of obtaining cerium oxide particles by reacting the composition for reaction in a supercritical fluid or a subcritical fluid,
wherein the ammonia precursor is a compound which forms a pyrolyzate comprising ammonia at an atmosphere of 80° C. or more, and
the cerium oxide particles have a particle size distribution of secondary particles according to Equation (1) below, which is 1.42 or less;
The particle size distribution=(D₉₀−D₁₀)/D₅₀ Equation (1)
where in the Equation (1),
the D₁₀ refers to a particle size of a spot of 10% from a cumulative particle size distribution curve,
the D₅₀ refers to a particle size of a spot of 50% from the cumulative particle size distribution curve, and
the D₉₀ refers to a particle size of a spot of 90% from the cumulative particle size distribution curve.

9. The manufacturing method of cerium oxide particles of claim 8,
wherein the ammonia precursor comprises urea.

10. The manufacturing method of cerium oxide particles of claim 8,
wherein the cerium precursor comprises a nitrogen element in a molecule thereof.

11. The manufacturing method of cerium oxide particles of claim 8,
wherein the reaction of the synthesis step proceeds in an atmosphere of 250° C. or more.

12. The manufacturing method of cerium oxide particles of claim 8,
wherein the composition for reaction has a solution form in which the cerium precursor and the ammonia precursor are dispersed therewith.

13. The manufacturing method of cerium oxide particles of claim 10,
wherein the composition for reaction comprises the ammonia precursor to have a mole ratio of the nitrogen element to the ammonia, which is 0.7 to 1.5.

14. The manufacturing method of cerium oxide particles of claim 8,
wherein the composition for reaction comprises a metal precursor for doping in an amount of 0.5 to 1 part by weight based on the cerium precursor of 100 parts by weight.

15. The manufacturing method of cerium oxide particles of claim 8,
wherein the composition for reaction comprises the ammonia precursor in an amount of 15 to 60 parts by weight based on the cerium precursor of 100 parts by weight.
